(19) United States
(12) Patent Application Publication
(10) Pub. No.: US 2010/0230672 A1
(43) Pub. Date: Sep. 16, 2010

(54) PRODUCTION OF INTEGRATED CIRCUITS COMPRISING DIFFERENT COMPONENTS

(75) Inventor: Wolfgang Schnitt, Norderstedt (DE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/161,705

(22) PCT Filed: Jan. 25, 2007
(86) PCT No.: PCT/IB07/50260

§ 371 Date: Jul. 22, 2008

(30) Foreign Application Priority Data
Jan. 26, 2006 (EP) 06100869.4

(51) Int. Cl. H01L 23/58; H01L 21/66

(52) U.S. Cl. 257/48; 438/18; 257/E21.531; 257/E23.141

(57) ABSTRACT

It is described a method for producing an integrated circuit element comprising a first electric component of a first type and a second electric component of a second type, wherein the two components require different measurement conditions for testing the components as to be defective or as to be defect free. The production method comprises the steps of (a) forming the first and the second component on a substrate, (b) providing a conductor path on the substrate in order to contact the first and the second component, the conductor path comprising a galvanic gap, wherein the galvanic gap provides the possibility to individually connect the first component with a measurement device, (c) accomplishing a test of the first component with the measurement device and (d) in case the test shows a defect free first component, closing the galvanic gap with a conductive connection, and in case the test shows a defective first component, identifying the corresponding integrated circuit element as to be defective. Furthermore, there is described a method for producing an integrated circuit comprising a plurality of circuit elements, a circuit element and an integrated circuit.

The present invention relates to the field of integrated circuits. In particular, the present invention relates to methods for producing integrated circuit elements and integrated circuits, wherein the circuit elements and the circuits comprise at least two different types of components, a first electric component of a first type and a second electric component of a second type. The first electric component requires a first measurement condition for testing the first component and the second electric component requires a second measurement condition for testing the second component. The present invention further relates to circuit elements and to circuits, which may be produced with the above mentioned production methods.

In order to produce reliable discrete electronic circuits comprising e.g. ferroelectric capacitors, it is well known to test these electronic circuits before they are delivered to customers who purchase electronic products wherein the expect a long life cycle of the product. A known test technique includes the so-called “Burn In method”, wherein testing voltages pulses are applied to the capacitors in order to stimulate an early failure of defective capacitors. Therefore, circuits with defective components can be separated out from the production process.

The document U.S. Pat. No. 5,853,603 discloses a method for manufacturing a microelectronic device containing a plurality of interconnected elements, which are arranged on a substrate. The manufacturing method itself comprises the steps of manufacturing cells of elements containing a circuit with a plurality of individual components on the substrate and testing these cells in order to distinguish the valid cells. The method further comprises the step of forming junction bands in an electrical conductive material connecting at least one valid cell. Thereby, larger electronic circuits may be produced with an appropriate discrete wiring of defect-free elements such that the defect-free elements are interconnected in a proper way. However, when a defective element is identified the complete element comprising a plurality of components has to be discarded from the forthcoming step of interconnecting defect-free elements.

There may be a need for an economically improved method for producing integrated circuits each comprising different electric components.

This need may be met by a method for producing an integrated circuit element as set forth in claim 1. According to this aspect of the invention the circuit element which is supposed to be produced comprises a first electric component of a first type and a second electric component of a second type, wherein the first electric component requires a first measurement condition for testing the first component and the second electric component requires a second measurement condition for testing the second component. The two measurement conditions differ from each other. The method for producing the circuit element comprises the steps of (a) forming the first and the second component on a substrate, (b) providing a conductor path on the substrate in order to contact the first and the second component, the conductor path comprising a galvanic gap, wherein the galvanic gap provides the possibility to individually connect the first component with a measurement device, (c) accomplishing a test of the first component with the measurement device and (d) in case the test shows a defect free first component, closing the galvanic gap with a conductive connection, and in case the test shows a defective first component, identifying the corresponding integrated circuit element as to be defective.

The described method provides the advantage, that the quality of a circuit element can be tested on the basis of individual electric components at an early stage of the production process. For building larger integrated circuits comprising a plurality of circuit elements identified defective circuit elements can be discarded such that the waste rate for defective circuits comprising a plurality of circuit elements can be dramatically reduced. Consequently, the production costs can be reduced significantly.

According to an embodiment of the present invention as set forth in claim 2, the step of accomplishing a test of the first component comprises the steps of (a) applying a voltage pulse to the first component and (b) measuring the resistance of the first component. The resistance can be measured easily by measuring the current flowing through the first component when a predefined DC-voltage or AC-voltage is applied to the component. Preferably, the testing procedure includes first applying a certain test signal comprising a defined sequence of voltage pulse and than measuring the ohm resistance of the tested component. Such a testing procedure is typically called a “flash test”.

It has to be pointed out that due to the galvanic separation of the first and the second component each electric component may be tested with the appropriate measurement signal. Limitations regarding the measurement signal for other components do not have to be taken into account when the optimal testing conditions are chosen.

According to a further embodiment of the invention as set forth in claim 3, the measurement device is electrically connected to the first component by means of electrodes. Preferably, each electrode comprises a sharp spike such that a contacting of small pad such as a land or a conductor junction area formed on the conductor path is possible. The electrodes may be formed in a shape of needles.

According to a further embodiment of the invention as set forth in claim 4, the step of forming the first and the second component on a substrate and the step of providing a conductor path on the substrate are carried out at a first location and the step of accomplishing a test of the first component with the measurement device is carried out at a second location different from the first location. The first location may preferably be a clean room for manufacturing semiconductor circuits. The second location may be a special laboratory comprising the appropriate measurement devices. In particular the second location may be a so-called wafer test center wherein the above-mentioned flash test can be carried out effectively.

According to a further embodiment of the invention as set forth in claim 5, a metal layer is used for closing the galvanic gap. Preferably a metal multilayer may be used. This may provide the advantage that well known techniques for applying a metallization may be used for closing the galvanic gap. Therefore, the method can be carried out with common apparatuses used for metallization and/or for forming and structuring metallic multilayer structures.

The above-mentioned need may further be met by a method for producing an integrated circuit as set forth in claim 6. According to this aspect of the invention the method comprises the steps of (a) producing a plurality of integrated circuit elements by repeatedly applying one or more of the above described methods for producing integrated circuit elements and (b) interconnecting a selection of the plurality of integrated circuit elements which selection comprises only defect free first components.

The described method represents an effective way for producing integrated circuits comprising a plurality of discrete circuit elements. A production of defective circuits can be avoided when all circuit elements are tested as to be defect-free before the circuit elements being interconnected with each other.

It has to be noted that the sequence of steps is arbitrary. For instance, it is possible that first the electric components including the conductor paths are formed on the substrate and second the components of the first type are successively tested. The testing procedure can be carried out with all components of each integrated circuit element. Alternatively, the testing procedure can be carried out with a predefined selection of electric components.

According to a further embodiment of the invention as set forth in claim 7, the substrate is a wafer and the test results of components are saved in a map of the wafer. This so called wafer mapping provides the advantage, that the wafer can be further processed effectively wherein all relevant data of the components formed on the wafer can be forwarded to an apparatus of a machine carrying out steps for further processing the wafer.

According to a further embodiment of the invention as set forth in claim 8, the method further comprises the step of connecting in a predefined order integrated circuit elements showing a positive result. This may provide the advantage that electric components comprising discrete integrated circuit elements can be produced in a very effective and economic way. A process with a high reliability may be guaranteed due to the possibility to separate out defective circuit elements from the production process for the electric component.

According to a further embodiment of the invention as set forth in claim 9, the method further comprises the step of singularizing the integrated circuit comprising a defined number of interconnected circuits elements. This may have the advantage that an in particular effective method for producing discrete integrated electric components is provided. Preferably, the singularizing is carried out directly by a separation of a wafer substrate. Techniques for separating wafer into small bare dies are well known by experts in the field of producing semiconductor components.

According to a further aspect of the present invention as set forth in claim 10, there is provided an integrated circuit element. The circuit element comprises a first electric component of a first type and a second electric component of a second type, wherein the first electric component requires a first measurement condition for testing the first component and the second electric component requires a second measurement condition for testing the second component. The two measurement conditions differ from each other. The circuit element further comprises a conductor path provided on a substrate for contacting the first and the second component, the conductor path comprising a galvanic gap, wherein the galvanic gap provides the possibility to individually connect the first component with a measurement device.

This aspect of the invention is based on the idea that the described design of the integrated circuit element and in particular the design of the conductor path provides the useful possibility, that the first component within the circuit element may be tested individually without affecting the second or further components of the circuit element. Therefore, optimal measurement conditions for the first component may be applied without any limitations due to restricted measurement conditions for components of the second type. Such restricted measurement condition may be for instance a limited maximum voltage, which may be allowed for being applied without a deterioration of the second component.

According to an embodiment of the invention as set forth in claim 11, the first component is a non-semiconductor-compatible component. Since non-semiconductor components usually allow much more stressing measurement conditions the non-semiconductor components may be tested by applying the appropriate measurement conditions.

According to a further embodiment of the invention as set forth in claim 12, the first component is a capacitor. In particular the first component may be a ferroelectric capacitor. A ferroelectric capacitor is a component comprising a spontaneous polarization which orientation might be changed by applying an electric field. With a ferroelectric capacitor new types of microelectronic circuits may be provided. As an example of a very interesting new type of microelectronic circuits Ferroelectric Random Access Memories (FRAM) have to be mentioned, which may be used computer products as non-volatile memories.

It has to be noted that according to further embodiments not described explicitly different kinds of components may be used as components of the first type. The only constraint for the different kinds of components is that the allowable testing conditions differ from the testing conditions, which have to be used for semiconductors. For instance, any capacitors with a high breakthrough voltage, varistors or spark gaps may be employed as components of the first type.

In order to perform reliable test on capacitors so-called flash tests can be carried out. Flash tests typically include a stressing of the capacitor with a sequence of high voltage pulses, which sequence is applied to the plates of the capacitor. Typically, voltage pulse having an amplitude between 10 V and 100 V may be applied. The exact amplitude of the applied voltage depends on the thickness of a dielectric layer located between the plates of the capacitor.

Preferably, the maximum voltage, which is applied during the flash test, is selected such that the dielectric layer of a defect-free capacitor would not be damaged. By contrast to defect-free capacitors, a defective dielectric layer would suffer from an electric breakthrough. Thereby, the corresponding capacitors are destroyed and show a much higher leakage current compared with defect-free capacitors. Therefore, a measurement of the leakage current may allow for a separation of defect capacitors from defect-free capacitors.

It has to be pointed out that in order to provide a test exhibiting a maximum reliability the voltage pulses may be applied under different thermal conditions of the circuit element.

According to a further embodiment of the invention as set forth in claim 13, the second component is a semiconductor-compatible component. Due to the electrically decoupling between the second component and the first component the damageable second component may be protected from the stressing measurement conditions which may be applied to the first component.

According to a further embodiment of the invention as set forth in claim 14, the second component is a diode. In particular the second component is an Electro Static Discharge diode (ESD diode), which is arranged in proximity to an easy damageable semiconductor component. An ESD diode may be used in order to protect the semiconductor component against voltage overloads due to unwanted electrostatic charge flowing onto the terminals of the semiconductor component.

During the manufacturing process of the integrated circuit element the galvanic gap providing a temporarily separation of the diodes from the first components may allow a testing of the first component with appropriate voltage signals. These testing conditions are not restricted to the more smooth measurement conditions, which are adequate for the diodes. Usually, semiconductor components like diodes allow only a component testing with a very low voltage compared to other non-semiconductor components. Therefore, the circuit element can be tested effectively by applying the appropriate measurement conditions for each type of the electric components.

According to a further embodiment of the invention as set forth in claim 15, the integrated circuit element further comprises a third electric component of a third type. This may provide the advantage that also components formed in circuit elements comprising three or even more different types of components may be individually tested in order to ensure that the circuit element is not defective due to individual defect components.

According to a further embodiment of the invention as set forth in claim 16, the third component is a resistor. This may provide the possibility that various types of circuit elements may be produced in an effective and reliably way. For instance, such circuit elements may represent low-pass filter, high-pass filter or any other electronic circuits comprising a resistor.

According to a further embodiment of the invention as set forth in claim 17, the conductor path comprises at least two contact pads, which are located at two opposite sides of the gap, respectively. This may allow for an easy contacting of the component via electrodes belonging to the measurement device.

According to a further embodiment of the invention as set forth in claim 18, the galvanic gap is closed with a metallic layer. In particular, the galvanic gap may be closed with a metallic multilayer. Preferably the metallic multilayer is a so-called Under Bump Metal (UBM). On the surface of the UBM solder balls may be formed at appropriate locations. The solder balls may be connected with lands provided on a printed circuit board. The chip and the printed circuit board may be connected permanently e.g. with a soldering process which might be carried out e.g. be means with a so-called reflow oven.

The UBM may comprise different metal layers including copper, nickel, silver and/or gold. In order to provide for a selective metallization of the circuit element the UBM might be structured before the solder balls are formed at the appropriate locations on the surface of the corresponding chip.

According to a further aspect of the present invention as set forth in claim 19, there is provided an integrated circuit. The integrated circuit comprises a plurality of integrated circuit elements, which have been described above. The integrated circuit, which preferably may be formed directly on a wafer substrate, may be a so called Wafer-Level-Package or Chip-Size-Package.

The quality of an integrated circuit comprising a plurality of circuit elements can be guaranteed by using integrated circuit elements, which include defect-free components only.

It has to be noted that certain embodiments of the invention have been described with reference to production methods and other embodiments of the invention have been described with reference to an integrated circuit element or with reference to an integrated circuit. However, a person skilled in the art will gather from the above and the following description that, unless other notified, any combination between features of the method claims and features of the circuit claims is possible and is disclosed with this application.

The aspects defined above and further aspects of the present invention are apparent from the examples of embodiment to be described hereinafter and are explained with reference to the examples of embodiment. The invention will be described in more detail hereinafter with reference to examples of embodiment but to which the invention is not limited.

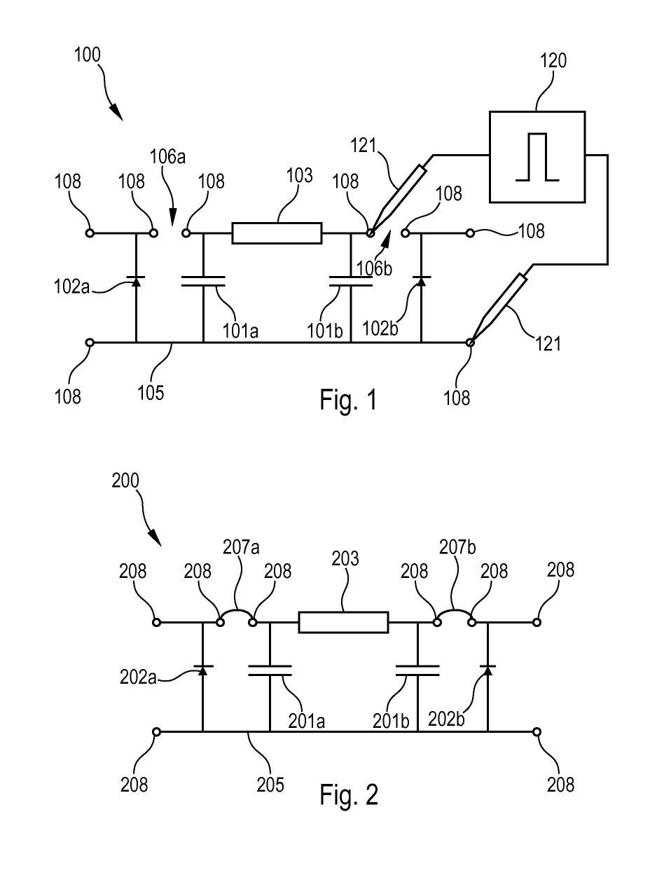

FIG. 1 shows a measurement arrangement for selectively testing a capacitor provided in a low pass filter.

FIG. 2 shows the low pass filter depicted in FIG. 1, wherein after testing the capacitors galvanic gaps have been closed.

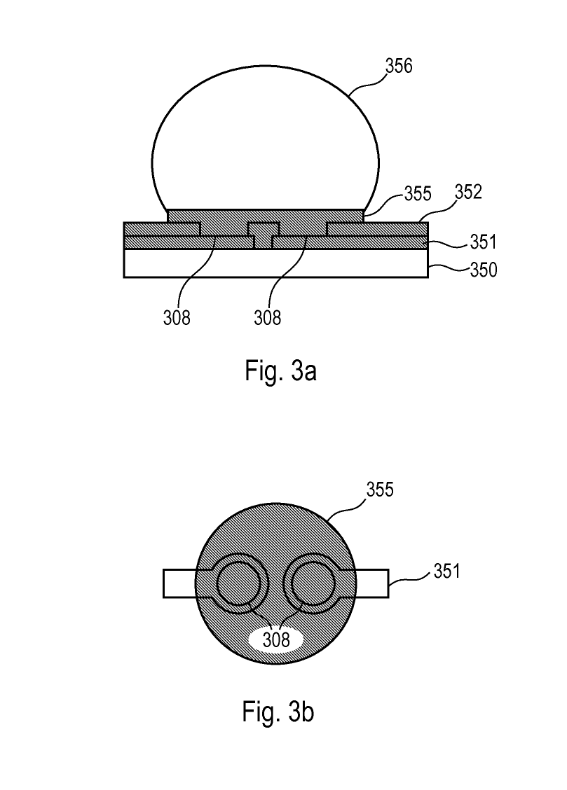

FIG. 3a shows a side view of a contact bridge for closing a galvanic gap.

FIG. 3b shows a top view of the contact bridge depicted in FIG. 3a.

The illustration in the drawing is schematically. It is noted that in different drawings, similar or identical elements are provided with the same reference signs or with reference signs, which are different from each other only within the first digit.

FIG. 1 shows a circuit diagram depicting an integrated circuit element 100 according to an embodiment of the present invention. The circuit element 100 represents a low pass filter comprising various electric components, which are arranged or formed on a substrate (not shown). Preferably, the substrate is a silicon wafer.

The components include two capacitors 101a and 101b, two diodes 102a and 102b and one resistor 103. The capacitors 101a and 101b are ferroelectric capacitors. The diodes 102a and 102b are ESD protection diodes. However, the different types of components are shown as an example only. It will be understood from the foregoing and the following description that the invention might be realized also with other types of components.

The components representing the low pass filter 100 are electrically coupled with each other directly or indirectly via a conductor path 105. The conductor path 105 is formed from a structured metal layer, preferably a structured aluminium layer. As can be seen from FIG. 1, the conductor path 105 comprises two recesses or gaps 106a and 106b, which represent open bridges. On the left and on the right side of each gap 106a and 106b, there are provided junction areas 108. Further junction areas 108 are also provided at the input and at the output of the integrated low pass filter 100, such that the low pass filter 100 might be electrically coupled with other circuit elements, e.g. other integrated low pass filter 100 of the same type.

Before the electric circuit element 100 is further processed, it is desirable to individually test the components whether the individual component is defective. A defective component would cause the whole circuit element 100 as to be defective. In this context a component is classified as to be defective not only if the component is defective from the beginning. A component is also classified as to be defective if the estimated life cycle compared to the specified life cycle for that type of component is reduced. Such a defective component can be identified by a stressing procedure and are forthcoming testing procedure.

Such a stressing procedure, which is called a flash test, is in particular applicable for capacitors. Thereby, high voltage pulses are loaded to the plates of the capacitor. Typically, voltage pulses with amplitudes between 10 V and 100 V are applied. The exact voltage depends on the thickness of a dielectric layer, which is located between the capacitor plates. The maximum voltage, which might be loaded during the flash test, is selected such that the dielectric layer of a defect-free capacitor is not damaged. By contrast to the defect-free capacitors, a defective dielectric layer suffers from the stressing procedure and shows an electric breakthrough. Thereby, the corresponding capacitors are destroyed and, in a following testing procedure, which includes the measurement of the resistance of the previous stressed component, a defective component typically shows an increased leakage current.

Since different components require different procedures in order to identify a defective state there might occur the problem that due to the electrically coupling an appropriate testing procedure for a first type of components (here the capacitors 101a and 101b) might cause damages even to defect free components of a second type (here the diodes 102a and 102b).

The galvanic gap 106a or 106b provides the possibility to individually connect the capacitor 101a or 101b with an electric measurement device 120, respectively. As can be seen from FIG. 1, even if a high voltage pulse would be loaded on the capacitor 101b, a damage of the diode 102b can be avoided because only one side of the diode 102b is electrically connected with the measurement device 120. In other words, the galvanic gap 106b exhibits an open circuit such that the voltage signal provided by the measurement device 120 is not loaded to the diode 102b. Therefore, the galvanic gap 106b provides the possibility to apply an appropriate stressing procedure to the capacitor 101b only. The optimal stressing procedure can be selected without taking into account the maximal voltages, which might be loaded on the diode 102b. Since the diode 102b is a semiconductor component, the maximum voltage for the diode 102b is typically much lower than the maximum voltage for the capacitor 101b, which is a non-semiconductor component.

It will be understood that the same rules apply to the stressing conditions, which are applicable to the capacitor 101a and the diode 102a.

The capacitor 101b is connected with the measurement device 120 by means of electrodes 121. The electrodes 121 are in contact with two junction areas 108, wherein a first junction area 108 is electrically connected with a first plate of the capacitor 101b and the second junction area 108 is electrically connected with a second plate of the capacitor 101b. The junction area 108 allows for a reliable electrical contact between the corresponding portion of the conductor path 105 and the electrode 121 of the electric measurement device 120.

Since integrated circuits are typically formed within small packages, the junction areas 108 are also restricted in size. In order to enable a stable and reliable contact between the component 101b, which is supposed to be tested, each electrode 121 comprises a sharp spike such that a contacting of a small junction area 108 is possible. Preferably, the electrodes 121 are formed in the shape of needles.

In the following it will be assumed that the stressing and the testing procedures, which have been are applied to the capacitors 101a and 101b, indicated that both capacitors 101a and 101b are defect-free. Furthermore, it will be assumed that also the other components and the conductor path are defect-free such that the integrated circuit element 100 might be further processed.

For further processing, the galvanic gaps 106a and 106b have to be closed in order to produce a faultless circuit element 100.

FIG. 2 shows the circuit element 100 known from FIG. 1 with closed galvanic gaps. The circuit element is now denoted with reference sign 200. The two galvanic gaps 106a and 106b are closed with a bridge circuit 207a and another bridge circuit 207b, respectively.

FIGS. 3a and 3b show in more detail the construction of the bridge circuits 207a and 207b formed over the galvanic gaps 106a and 106b, respectively. The bridge is formed between two junction areas 308 representing the borders of a galvanic gap. The junction areas 308, which might also be denoted as lands or contact pads, are formed on/structured from an aluminium layer 351. The aluminium layer 351, which together with the components shown in FIGS. 1 and 2 is formed on a substrate 350, also represents the conductor path 105. Preferably, the substrate 350 is a silicon wafer.

In order to protect the surface of the circuit element 100 from mechanical damages a protection layer 352 is provided on the upper surface of the substrate 350 and the aluminium layer 351, respectively. In the region above the two junction areas 308 the protection layer 352 comprises recesses, such that the upper surfaces of the two junction areas 308 is kept free for both electrically coupling the measurement device 120 with the circuit element and for forming a bridge circuit 355.

The bridge circuit 355 is made from a metal, which preferably is a multilayer metal. More preferably, the metal is a so-called Under Bump Metal (UBM). The UBM may comprise different metal layers including copper, nickel, silver and/or gold. In order to provide for a spatially selective coating the UBM is structured before a solder ball 356 is deposited on the bridge circuit 355. The use of the UBM has the advantage that solder balls 356 might be formed firmly on the surface of the integrated circuit element.

It has to be pointed out that the described method to electrically bridge the galvanic gaps can also be used to provide an interconnection between different circuit elements 100 such that an integrated circuit is formed on the substrate 350, wherein the integrated circuit may comprise a plurality of circuit elements 100. In case all the employed circuit elements 100 have been tested by stressing and testing procedures as described above, it can be guaranteed that not only the individual circuit elements 100 but also the whole integrated circuit is defect-free. Since the testing of the individual circuit elements 100 is carried out early within the production and manufacturing process of the integrated circuit, defective circuit elements 100 can be discarded at an early stage of the production process and the production rate for defective circuits can be reduced significantly.

It should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

In order to recapitulate the above described embodiments of the present invention one can state:

It is described a method for producing an integrated circuit element comprising a first electric component of a first type and a second electric component of a second type, wherein the two components require different measurement conditions for testing the components as to be defective or as to be defect free. The production method comprises the steps of (a) forming the first and the second component on a substrate, (b) providing a conductor path on the substrate in order to contact the first and the second component, the conductor path comprising a galvanic gap, wherein the galvanic gap provides the possibility to individually connect the first component with a measurement device, (c) accomplishing a test of the first component with the measurement device and (d) in case the test shows a defect free first component, closing the galvanic gap with a conductive connection, and in case the test shows a defective first component, identifying the corresponding integrated circuit element as to be defective.

Furthermore, there is described a method for producing an integrated circuit comprising a plurality of circuit elements, a circuit element and an integrated circuit.

1. A method for producing an integrated circuit element,
which comprises
a first electric component of a first type and a second electric component of a second type, wherein
the first electric component requires a first measurement condition for testing the first component and the second electric component requires a second measurement condition for testing the second component, the method comprising the steps of
forming the first component and the second component on a substrate,
providing a conductor path on the substrate in order to contact the first component and the second component, the conductor path comprising a galvanic gap, wherein the galvanic gap provides the possibility to individually connect the first component with a measurement device,
accomplishing a test of the first component with the measurement device and
in case the test shows a defect free first component, closing the galvanic gap (106a, 106b) with a conductive connection, and
in case the test shows a defective first component, identifying the corresponding integrated circuit element as to be defective.

2. A method according to claim 1, wherein
the step of accomplishing a test of the first component comprises the steps of
applying a voltage pulse to the first component and
measuring the resistance of the first component.

3. A method according to claim 1, wherein
the measurement device is electrically connected to the first component by electrodes.

4. The method according to claim 1, wherein
the step of forming the first component and the second component on a substrate and the step of providing a conductor path on the substrate are carried out at a first location and
the step of accomplishing a test of the first component with the measurement device is carried out at a second location which is different from the first location.

5. The method according to claim 1, wherein
in order to close the galvanic gap a metal layer and preferably a metal multilayer is used.

6. A method for producing an integrated circuit, the method comprising the steps of
producing a plurality of integrated circuit elements by repeatedly applying the method according to claim 1, and
interconnecting a selection of the plurality of integrated circuit elements which selection comprises only defect free first components.

7. The method according to claim 6, wherein
the substrate is a wafer and
the test results of components are saved in a map of the wafer.

8. The method according to claim 6, further comprising the step of
connecting in a predefined order integrated circuit elements showing a positive result.

9. The method according to claim 8, further comprising the step of
singularizing the integrated circuit comprising a defined number of interconnected circuits elements.

10. An integrated circuit element comprising
a first electric component of a first type and a second electric component of a second type, wherein
the first electric component requires a first measurement condition for testing the first component and the second electric component requires a second measurement condition for testing the second component, and
a conductor path provided on a substrate for contacting the first component and the second component, the conductor path comprising a galvanic gap, wherein the galvanic gap provides the possibility to individually connect the first component with a measurement device.

11. The integrated circuit element according to claim 10, wherein
the first component is a non-semiconductor-compatible component.

12. The integrated circuit element according to claim 11, wherein
the first component is a capacitor, in particular a ferroelectric capacitor.

13. The integrated circuit element according to claim 10, wherein
the second component is a semiconductor-compatible component.

14. The integrated circuit element according to claim 13, wherein
the second component is a diode, in particular a ESD-protection diode.

15. The integrated circuit element according to claim 10, further comprising
a third electric component of a third type.

16. The integrated circuit element according to claim 15, wherein
the third component is a resistor.

17. The integrated circuit element according to claim 10, wherein
the conductor path comprises at least two contact pads which are located at two opposite sides of the gap, respectively.

18. The integrated circuit element according to claim 10, wherein the galvanic gap is closed with a metallic layer, in particular with a metallic multilayer.

19. An integrated circuit comprising
a plurality of integrated circuit elements according according to claim 10.
